(19) United States
(12) Patent Application Publication
(10) Pub. No.: US 2017/0018371 A1
(43) Pub. Date: Jan. 19, 2017

(54) PEROVSKITE SOLAR CELL

(71) Applicant: Panasonic Corporation, Osaka (JP)

(72) Inventors: MICHIO SUZUKA, Osaka (JP); SHINYA FUJIMURA, Osaka (JP); RYUSUKE UCHIDA, Osaka (JP); NAOKI HAYASHI, Kyoto (JP)

(21) Appl. No.: 15/190,186

(22) Filed: Jun. 23, 2016

(30) Foreign Application Priority Data
Jul. 14, 2015 (JP) 2015-140172

(51) Int. Cl. H01G 9/20; H01L 51/44; H01L 51/00; H01L 51/42

(52) U.S. Cl. CPC H01G 9/2059; H01L 51/4213; H01L 51/441; H01G 9/2031; H01L 51/005

(57) ABSTRACT

A perovskite solar cell includes: a first electrode; an electron transport layer on the first electrode, containing a semiconductor; a porous layer on the electron transport layer, containing a porous material; a light-absorbing layer on the porous layer, containing a first compound and a second compound different from the first compound, the first compound having a perovskite structure represented by a compositional formula ABX3 where A represents a monovalent cation, B represents a divalent cation, and X represents a halogen anion, the second compound containing the divalent cation; and a second electrode on the light-absorbing layer. A ratio of a number of moles of the monovalent cation in the light-absorbing layer to a number of moles of the divalent cation in the light-absorbing layer is 0.5 or more and 0.9 or less.

### BACKGROUND

1. Technical Field

The present disclosure relates to a perovskite solar cell. 2. Description of the Related Art

In recent years, researches on the development of perovskite solar cells have been underway, the perovskite solar cells using, as a light-absorbing material, a perovskite crystal represented by a compositional formula ABX₃ (A represents a monovalent cation, B represents a divalent cation, and X represents a halogen anion) or a perovskite-like structure. Jeong-Hyeok Im et al. “Nature Nanotechnology” (US), vol. 9, p. 927-932, November 2014 discloses a perovskite solar cell having a CH₃NH₃PbI₃ perovskite layer as the light-absorbing material.

### SUMMARY

There has been a demand for a perovskite solar cell having higher durability.

In one general aspect, the techniques disclosed here feature a perovskite solar cell including: a first electrode; an electron transport layer on the first electrode, containing a semiconductor; a porous layer on the electron transport layer, containing a porous material; a light-absorbing layer on the porous layer, containing a first compound and a second compound different from the first compound, the first compound having a perovskite structure represented by a compositional formula ABX3 where A represents a monovalent cation, B represents a divalent cation, and X represents a halogen anion, the second compound containing the divalent cation; and a second electrode on the light-absorbing layer. A ratio of a number of moles of the monovalent cation in the light-absorbing layer to a number of moles of the divalent cation in the light-absorbing layer is 0.5 or more and 0.9 or less.

It should be noted that general or specific embodiments may be implemented as an element, a device, a system, an integrated circuit, a method, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a sectional view of a perovskite solar cell according to a first embodiment of the present disclosure;

FIG. 2 is a sectional view of a perovskite solar cell according to a second embodiment of the present disclosure; and

FIG. 3 is a sectional view of a perovskite solar cell according to a third embodiment of the present disclosure.

### DETAILED DESCRIPTION

Prior to descriptions of embodiments of the present disclosure, the findings having been found by the inventor will be described. The perovskite solar cell disclosed by Jeong-Hyeok Im et al. “Nature Nanotechnology” (US), vol. 9, p. 927-932, November 2014 has a problem of low durability. One of the causes of the low durability is decomposition of the compound having a perovskite structure in the light-absorbing layer. In the following descriptions, the “compound having a perovskite structure” is sometimes referred to as a “perovskite compound”. The cause of decomposition of the perovskite compound is probably as follows: during production of the perovskite compound represented by a compositional formula ABX₃, a halide AX as a raw material remains unreacted in the resultant light-absorbing layer; and the halide AX causes a decomposition reaction of the perovskite compound ABX₃.

In contrast, an aspect according to the present disclosure provides a perovskite solar cell having high durability.

### First Embodiment

Hereinafter, an embodiment of the present disclosure will be described with reference to a drawing.

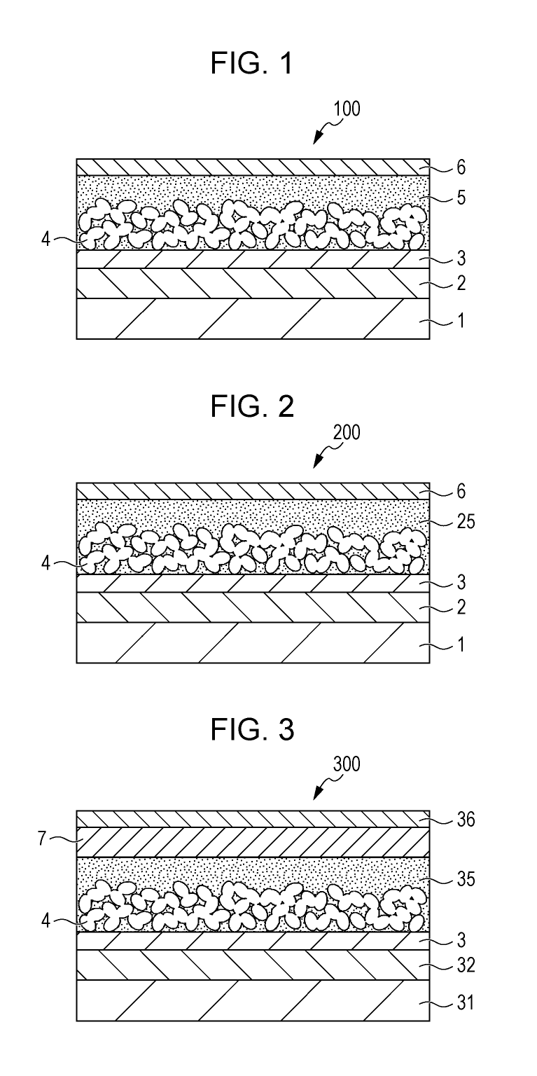

Referring to FIG. 1, a perovskite solar cell 100 according to a first embodiment has a configuration in which, on a substrate 1, a first current-collector electrode 2, an electron transport layer 3, a porous layer 4, a light-absorbing layer 5, and a second current-collector electrode 6 are stacked in this order. The electron transport layer 3 contains a semiconductor. The porous layer 4 contains a porous material. The porous material includes pores. The light-absorbing layer 5 contains a first compound having a perovskite structure represented by a compositional formula ABX₃, and a second compound containing B and being different from the first compound. In the formula ABX₃, A represents a monovalent cation, B represents a divalent cation, and X represents a halogen anion. For the light-absorbing layer 5, the ratio of the number of moles of the cation A to the number of moles of the cation B is 0.5 or more and 0.9 or less.

Note that the substrate 1 may be omitted from the perovskite solar cell 100.

The pores in the porous layer 4 form an open porous structure extending from the boundary between the porous layer 4 and the light-absorbing layer 5 to the boundary between the porous layer 4 and the electron transport layer 3. Thus, when the material for the light-absorbing layer 5 is placed on the porous layer 4, the material fills the pores of the porous layer 4 and reaches the surface of the electron transport layer 3. The light-absorbing layer 5 is thus in contact with the electron transport layer 3, which enables direct exchange of electrons therebetween.

The basic operation and effect of the perovskite solar cell 100 according to the embodiment are as follows.

Upon entry of light into the perovskite solar cell 100, the light-absorbing layer 5 absorbs the light to generate excited electrons and holes. These excited electrons move through the electron transport layer 3 to the first current-collector electrode 2. On the other hand, the holes generated in the light-absorbing layer 5 move to the second current-collector electrode 6. Thus, the perovskite solar cell 100 produces current between the first current-collector electrode 2 as the negative electrode and the second current-collector electrode 6 as the positive electrode.

In addition, the ratio of the number of moles of the cation A to the number of moles of the cation B in the light-absorbing layer 5 is 0.5 or more and 0.9 or less, to thereby provide a perovskite solar cell having high durability. The reason for this is as follows.

The perovskite compound ABX₃ in the light-absorbing layer 5 is synthesized from a halide AX and a halide BX₂, for example. When the ratio of the number of moles of the cation A to the number of moles of the cation B in the light-absorbing layer 5 is 0.5 or more and 0.9 or less, the amount of the cation A is at least 10% smaller than the amount of the cation B in the light-absorbing layer 5.

This means that substantially the whole amount of the cation A in the raw material has been consumed for formation of the perovskite compound ABX₃, so that the cation A in the form of halide AX probably no longer remains in the light-absorbing layer 5. Thus, the ratio of the number of moles of the cation A to the number of moles of the cation B in the light-absorbing layer 5 is set to 0.9 or less, to thereby increase the probability that the light-absorbing layer 5 contains the perovskite compound ABX₃ and the cation-B-containing compound alone. In other words, the probability that the halide AX causes the decomposition reaction of the perovskite compound ABX₃ is decreased, to thereby enhance the durability of the perovskite solar cell 100. On the other hand, from the standpoint of conversion efficiency, the ratio of the number of moles of the cation A to the number of moles of the cation B in the light-absorbing layer 5 is desirably 0.5 or more. In summary, the ratio of the number of moles of the cation A to the number of moles of the cation B in the light-absorbing layer 5 is desirably 0.5 or more and 0.9 or less, more desirably 0.8 or more and 0.9 or less.

The ratio of the number of moles of the cation A to the number of moles of the cation B in the light-absorbing layer 5 can be measured with, for example, an electron-beam microanalyzer (EPMA). When the perovskite compound ABX₃ in the light-absorbing layer 5 is, for example, CH₃NH₃PbI₃, the cation A is CH₃NH₃⁺ and the cation B is Pb²⁺. In this case, the number of moles of the cation A can be determined on the basis of the analysis result of carbon content and the number of moles of the cation B can be determined on the basis of the analysis result of lead content. On the basis of these determined numbers of moles, the ratio therebetween can be calculated.

The porous layer 4 is formed on the electron transport layer 3, so that the light-absorbing layer 5 is easily formed. Specifically, the porous layer 4 is formed, so that the material for the light-absorbing layer 5 enters the pores of the porous layer 4 and the porous layer 4 serves as the scaffold of the light-absorbing layer 5. Thus, the material for the light-absorbing layer 5 tends not to be repelled by or aggregate on the surface of the porous layer 4. Accordingly, the light-absorbing layer 5 can be formed as a uniform film.

The porous layer 4 causes light scattering, so that the optical length of light passing through the light-absorbing layer 5 is expected to increase. The increase in the optical length probably results in an increase in the amount of electrons and holes generated in the light-absorbing layer 5.

The perovskite solar cell 100 according to the embodiment can be produced by, for example, the following method. The first current-collector electrode 2 is formed on a surface of the substrate 1 by Chemical Vapor Deposition (CVD) or sputtering, for example. On the first current-collector electrode 2, the electron transport layer 3 is formed by sputtering, for example. On the electron transport layer 3, the porous layer 4 is formed by coating, for example. On the porous layer 4, the light-absorbing layer 5 is formed by coating, for example. On the light-absorbing layer 5, the second current-collector electrode 6 is formed. Thus, the perovskite solar cell 100 is produced.

Hereinafter, components of the perovskite solar cell 100 will be specifically described.

Substrate 1

The substrate 1 is an optional component. The substrate 1 supports layers of the perovskite solar cell 100. The substrate 1 can be formed of a transparent material. For example, the substrate 1 may be selected from glass substrates and plastic substrates (including plastic films). When the first current-collector electrode 2 has sufficiently high strength, the layers can be supported by the first current-collector electrode 2 and hence the substrate 1 may be omitted.

First Current-Collector Electrode 2

The first current-collector electrode 2 has conductivity. The first current-collector electrode 2 transmits light, for example, light ranging from the visible-light region to the near-infrared region. The first current-collector electrode 2 may be formed of a transparent and conductive metal oxide, for example. Examples of the metal oxide include indium-tin compound oxide, antimony-doped tin oxide, fluorine-doped tin oxide, zinc oxide doped with at least one of boron, aluminum, gallium, and indium, and composite materials of the foregoing. Alternatively, the first current-collector electrode 2 may be formed of an opaque material so as to have a light-transmitting pattern. Examples of the light-transmitting pattern include line patterns (striped patterns), wavy-line patterns, grid patterns (mesh patterns), punching-metal patterns (in which a large number of fine through-holes are arranged regularly or randomly), and inverse patterns of the foregoing patterns. The electrode having such a pattern allows light to pass through the openings where the electrode material is not present. Examples of the opaque electrode material include platinum, gold, silver, copper, aluminum, rhodium, indium, titanium, iron, nickel, tin, zinc, and alloys containing at least one of the foregoing. Alternatively, the first current-collector electrode 2 may be formed of a conductive carbon material.

The transmittance of the first current-collector electrode 2 may be, for example, 50% or more, or 80% or more. The wavelength of light that the first current-collector electrode 2 transmits is selected depending on the wavelength of light that the light-absorbing layer 5 absorbs. The first current-collector electrode 2 may have a thickness of 1 nm or more and 1000 nm or less, for example.

Electron Transport Layer 3

The electron transport layer 3 contains a semiconductor. In particular, the semiconductor desirably has a band gap of 3.0 eV or more. When the electron transport layer 3 is formed of a semiconductor having a band gap of 3.0 eV or more, visible light and infrared light are transmitted to reach the light-absorbing layer 5. Examples of the semiconductor include organic n-type semiconductors and inorganic n-type semiconductors.

Examples of the organic n-type semiconductors include imide compounds, quinone compounds, fullerene, and derivatives thereof. Examples of the inorganic n-type semiconductors include oxides of metal elements and perovskite oxides. Examples of the oxides of metal elements include oxides of Cd, Zn, In, Pb, Mo, W, Sb, Bi, Cu, Hg, Ti, Ag, Mn, Fe, V, Sn, Zr, Sr, Ga, and Cr. More specifically, an example is TiO₂. Examples of the perovskite oxides include SrTiO₃ and CaTiO₃.

Alternatively, the electron transport layer 3 may be formed of a material having a band gap of more than 6 eV. Examples of the material having a band gap of more than 6 eV include alkali-metal halides such as lithium fluoride, alkaline-earth-metal halides such as calcium fluoride, alkaline-earth-metal oxides such as magnesium oxide, and silicon dioxide. In such cases, in order for the electron transport layer 3 to transport electrons, the electron transport layer 3 is formed so as to have a thickness of 10 nm or less, for example.

The electron transport layer 3 may include plural layers that differ in their materials.

Porous Layer 4

The porous layer 4 serves as the scaffold for forming the light-absorbing layer 5. The porous layer 4 does not inhibit light absorption by the light-absorbing layer 5 or movement of electrons from the light-absorbing layer 5 to the electron transport layer 3.

The porous layer 4 contains a porous material. The porous material is, for example, a porous material including a mass of insulating particles or semiconductor particles. Examples of the insulating particles include aluminum oxide particles and silicon oxide particles. Examples of the semiconductor particles include inorganic semiconductor particles. Examples of the inorganic semiconductor include oxides of metal elements, perovskite oxides of metal elements, sulfides of metal elements, and metal chalcogenides. Examples of the oxides of metal elements include oxides of Cd, Zn, In, Pb, Mo, W, Sb, Bi, Cu, Hg, Ti, Ag, Mn, Fe, V, Sn, Zr, Sr, Ga, Si, and Cr. More specifically, an example is TiO₂. Examples of the perovskite oxides of metal elements include SrTiO₃ and CaTiO₃. Examples of the sulfides of metal elements include CdS, ZnS, In₂S₃, PbS, Mo₂S, WS₂, Sb₂S₃, Bi₂S₃, ZnCdS₂, and Cu₂S. Examples of the metal chalcogenides include CdSe, In₂Se₃, WSe₂, HgS, PbSe, and CdTe.

The porous layer 4 desirably has a thickness of 0.01 μm or more and 10 μm or less, more desirably 0.1 μm or more and 1 μm or less. The porous layer 4 desirably has high surface roughness. Specifically, a surface-roughness coefficient defined as effective area/projected area is desirably 10 or more, more desirably 100 or more. The projected area is the area of a shadow of an object, the shadow being cast behind the object when light is directed straight toward the front surface of the object. The effective area is the actual surface area of an object. The effective area is calculated from the volume of an object determined by the projected area and thickness of the object, and the specific surface area and bulk density of the material forming the object.

Light-Absorbing Layer 5

The light-absorbing layer 5 contains a compound having a perovskite structure represented by a compositional formula ABX₃. In the formula, A represents a monovalent cation. Examples of the cation A include monovalent cations that are alkali-metal cations and organic cations. More specifically, examples include a methylammonium cation (CH₃NH₃⁺), a formamidinium cation (NH₂CHNH₂⁺), and a cesium cation (Cs⁺). In the formula, B represents a divalent cation. Examples of the cation B include divalent cations of transition metal elements and groups 13 to 15 elements. More specifically, examples include Pb²⁺, Ge²⁺, and Sn²⁺. In the formula, X represents a monovalent anion such as a halogen anion. Each of the cation A site, the cation B site, and the anion X site may be occupied by plural ion species. Specific examples of the compound having a perovskite structure include CH₃NH₃PbI₃, NH₂CHNH₂PbI₃, CH₃CH₂NH₃PbI₃, CH₃NH₃PbBr₃, CH₃NH₃PbCl₃, CsPbI₃, and CsPbBr₃.

The thickness of the light-absorbing layer 5 may be selected depending on its degree of light absorption and may be, for example, 100 nm or more and 1000 nm or less. The light-absorbing layer 5 may be formed by coating with a solution, for example.

Second Current-Collector Electrode 6

The second current-collector electrode 6 has conductivity. The second current-collector electrode 6 does not form an ohmic contact with the light-absorbing layer 5. The second current-collector electrode 6 blocks entry of electrons from the light-absorbing layer 5: specifically, regarding holes and electrons generated in the light-absorbing layer 5, the second current-collector electrode 6 allows entry of holes alone but not entry of electrons. This is achieved with a material that has a Fermi level higher than the energy level at the top of the conduction band of the light-absorbing layer 5. Specific examples of the material include gold and carbon materials such as graphene.

### Second Embodiment

A perovskite solar cell 200 according to a second embodiment differs from the perovskite solar cell 100 according to the first embodiment in how the light-absorbing layer is defined. In most cases, perovskite solar cells according to the first embodiment are also perovskite solar cells according to the second embodiment. However, some perovskite solar cells belong to the first embodiment, but do not belong to the second embodiment, and vice versa.

Hereinafter, the perovskite solar cell 200 will be described. However, components that have the same functions and configurations as those of components having been described for the perovskite solar cell 100 according to the first embodiment are denoted by the same reference numerals as in the first embodiment and descriptions thereof will be omitted.

Referring to FIG. 2, the perovskite solar cell 200 according to the second embodiment has a configuration in which, on a substrate 1, a first current-collector electrode 2, an electron transport layer 3, a porous layer 4, a light-absorbing layer 25, and a second current-collector electrode 6 are stacked in this order.

The light-absorbing layer 25 contains a perovskite compound represented by a compositional formula ABX₃ and a compound represented by a compositional formula BX₂. The measurement result by X-ray diffractometry for the light-absorbing layer 25 indicates that the peak intensity I[BX₂] derived from a (001) plane of the compound BX₂ is higher than the peak intensity I[ABX₃] derived from a (110) plane of the perovskite compound ABX₃. Herein, the term “peak intensity” means the height of a diffraction peak measured by X-ray diffractometry.

The substrate 1 may be omitted from the perovskite solar cell 200.

The basic operation and effect of the perovskite solar cell 200 according to the embodiment are as follows.

The operation of the perovskite solar cell 200 is the same as that of the perovskite solar cell 100 according to the first embodiment.

The measurement result by X-ray diffractometry for the light-absorbing layer 25 indicates that the peak intensity I[BX₂] derived from a (001) plane of the halide BX₂ is higher than the peak intensity I[ABX₃] derived from a (110) plane of the perovskite compound ABX₃. As a result, a perovskite solar cell having high durability is provided. The reason for this is as follows.

The perovskite compound ABX₃ in the light-absorbing layer 25 is synthesized from, for example, a halide AX and a halide BX₂. The measurement result by X-ray diffractometry for the light-absorbing layer 25 indicates that the peak intensity I[BX₂] derived from a (001) plane of the halide BX₂ is higher than the peak intensity I[ABX₃] derived from a (110) plane of the perovskite compound ABX₃. This means that the light-absorbing layer 25 has a relatively high content of the halide BX₂.

This means that substantially the whole amount of the cation A in the raw material has been consumed for formation of the perovskite compound ABX₃, so that the cation A in the form of halide AX probably no longer remains in the light-absorbing layer 25. Thus, the light-absorbing layer 25 is formed such that, in the measurement result by X-ray diffractometry, the peak intensity I[BX₂] derived from a (001) plane of the halide BX₂ is higher than the peak intensity I[ABX₃] derived from a (110) plane of the perovskite compound ABX₃, to thereby increase the probability that the light-absorbing layer 25 contains only both of the perovskite compound ABX₃ and the halide BX₂. Thus, the probability that the halide AX causes the decomposition reaction of the perovskite compound ABX₃ is decreased, so that the durability of the perovskite solar cell 200 is enhanced. When the ratio of the peak intensity I[BX₂] to the peak intensity I[ABX₃] is set to 3.5 or more, the durability can be further enhanced.

The perovskite solar cell 200 can be produced in the same manner as in the perovskite solar cell 100.

The light-absorbing layer 25 can be formed of the same material as that for the light-absorbing layer 5 according to the first embodiment.

### Third Embodiment

A perovskite solar cell 300 according to a third embodiment differs from the perovskite solar cell 100 according to the first embodiment in that the perovskite solar cell 300 further includes a hole transport layer.

Hereinafter, the perovskite solar cell 300 will be described. However, components that have the same functions and configurations as those of components having been described for the perovskite solar cell 100 according to the first embodiment are denoted by the same reference numerals as in the first embodiment and descriptions thereof will be omitted.

Referring to FIG. 3, the perovskite solar cell 300 according to the embodiment has a configuration in which, on a substrate 31, a first current-collector electrode 32, an electron transport layer 3, a porous layer 4, a light-absorbing layer 35, a hole transport layer 7, and a second current-collector electrode 36 are stacked in this order.

The substrate 31 may be omitted from the perovskite solar cell 300.

The basic operation and effect of the perovskite solar cell 300 according to the embodiment are as follows.

Upon entry of light into the perovskite solar cell 300, the light-absorbing layer 35 absorbs the light to generate excited electrons and holes. These excited electrons move to the electron transport layer 3. On the other hand, the holes generated in the light-absorbing layer 35 move to the hole transport layer 7. The electron transport layer 3 is connected to the first current-collector electrode 32. The hole transport layer 7 is connected to the second current-collector electrode 36. Thus, the solar cell 300 produces current between the first current-collector electrode 32 as the negative electrode and the second current-collector electrode 36 as the positive electrode.

The third embodiment provides the same effect as in the first embodiment.

However, in the third embodiment, the hole transport layer 7 is disposed. For this reason, the second current-collector electrode 36 is not necessarily required to block entry of electrons from the light-absorbing layer 35. Thus, the degree of freedom with which the material for the second current-collector electrode 36 is selected is enhanced.

Hereinafter, components of the perovskite solar cell 300 will be specifically described. Note that, for the same components as in the perovskite solar cell 100, descriptions will be omitted.

First Current-Collector Electrode 32 and Second Current-Collector Electrode 36

In the embodiment, since the hole transport layer 7 is disposed, the second current-collector electrode 36 is not necessarily required to block entry of electrons from the light-absorbing layer 35. In other words, the material for the second current-collector electrode 36 may be a material that forms an ohmic contact with the light-absorbing layer 35. Thus, the second current-collector electrode 36 may be formed so as to transmit light.

At least one of the first current-collector electrode 32 and the second current-collector electrode 36 transmits light and has the same configuration as that of the first current-collector electrode 2 in the first embodiment.

One of the first current-collector electrode 32 and the second current-collector electrode 36 may be formed so as not to transmit light. In other words, one of the electrodes is not necessarily formed of a material that transmits light or is not necessarily formed so as to have a pattern having openings.

Substrate 31

The substrate 31 may have the same configuration as that of the substrate 1 according to the first embodiment. When the second current-collector electrode 36 transmits light, a material that does not transmit light may be selected for the substrate 31. Examples of this material for the substrate 31 include metals, ceramics, and low-transmittance resin materials.

Light-Absorbing Layer 35

The light-absorbing layer 35 may have the same configuration as that of the light-absorbing layer 5 according to the first embodiment or the light-absorbing layer 25 according to the second embodiment.

Hole Transport Layer 7

The hole transport layer 7 is formed of an organic material or an inorganic semiconductor, for example. The hole transport layer 7 may include plural layers that differ in their materials.

Examples of the organic material include phenylamines and triphenylamine derivatives that contain a tertiary amine in the skeleton, and PEDOT compounds that have a thiophene structure. The organic material is not limited in terms of molecular weight and may have a high molecular weight. When such an organic material is used, the hole transport layer 7 is desirably formed so as to have a thickness of 1 nm or more and 1000 nm or less, more desirably 100 nm or more and 500 nm or less. When the hole transport layer 7 has a thickness in such a range, holes are sufficiently transported. In addition, a low resistance is maintained, so that photovoltaic power generation is carried out at high efficiency.

Examples of the inorganic semiconductor include p-type semiconductors such as CuO, Cu₂O, CuSCN, molybdenum oxide, and nickel oxide. When such an inorganic semiconductor is used, the hole transport layer 7 is desirably formed so as to have a thickness of 1 nm or more and 1000 nm or less, more desirably 10 nm or more and 50 nm or less. When the hole transport layer 7 has a thickness in such a range, holes are sufficiently transported. In addition, a low resistance is maintained, so that photovoltaic power generation is carried out at high efficiency.

The hole transport layer 7 may be formed by a coating process or a printing process. Examples of the coating process include doctor-blade coating, bar coating, spray coating, dip coating, and spin coating. An example of the printing process is screen printing. Optionally, plural materials may be mixed together and used to form the hole transport layer 7, and the hole transport layer 7 may be pressed or fired, for example. When the material for the hole transport layer 7 is a low-molecular-weight organic material or an inorganic semiconductor, the hole transport layer 7 may be formed by vacuum deposition, for example.

The hole transport layer 7 may contain a supporting electrolyte and a solvent. The supporting electrolyte and the solvent stabilize holes in the hole transport layer 7.

Examples of the supporting electrolyte include ammonium salts and alkali-metal salts. Examples of the ammonium salts include tetrabutylammonium perchlorate, tetraethylammonium hexafluorophosphate, imidazolium salts, and pyridinium salts. Examples of the alkali-metal salts include lithium perchlorate and potassium tetrafluoroborate.

The solvent contained in the hole transport layer 7 desirably has high ion conductivity. The solvent, which may be selected from aqueous solvents and organic solvents, is desirably selected from organic solvents in order to achieve higher stabilization of the solute. Specific examples of the solvent include heterocyclic compound solvents such as tert-butylpyridine, pyridine, and n-methylpyrrolidone.

The solvent may be an ionic liquid alone or a mixture of an ionic liquid and another solvent. Ionic liquids are desirable because of low volatility and high flame retardancy.

Examples of the ionic liquids include imidazolium-based ionic liquids such as 1-ethyl-3-methylimidazolium tetracyanoborate, pyridine-based ionic liquids, alicyclic amine-based ionic liquids, aliphatic amine-based ionic liquids, and azonium amine-based ionic liquids.

### EXAMPLES

Hereinafter, the present disclosure will be specifically described with reference to Examples. Perovskite solar cells of Examples 1 and 2 and Comparative Examples 1 to 3 were produced and evaluated in terms of properties.

### Example 1

A perovskite solar cell having the same structure as that of the perovskite solar cell 300 in FIG. 3 was produced. The perovskite solar cell includes the following components.

Substrate: glass substrate

First current-collector electrode: fluorine-doped SnO₂ layer (surface resistance: 10 Ω/sq.)

Electron transport layer: titanium oxide, 30 nm

Porous layer: porous titanium oxide

Light-absorbing layer: CH₃NH₃PbI₃, PbI₂

Hole transport layer: Spiro-OMeTAD (manufactured by Merck KGaA)

Second current-collector electrode: gold, 80 nm

The perovskite solar cell of Example 1 was produced in the following manner.

As the substrate and the first current-collector electrode, a conductive glass substrate (manufactured by Nippon Sheet Glass Co., Ltd.) having a fluorine-doped SnO₂ layer and having a thickness of 1 mm was used.

On the first current-collector electrode, a titanium oxide layer having a thickness of about 30 nm was formed by sputtering as an electron transport layer.

A high-purity titanium oxide powder having an average primary particle size of 20 nm was dispersed in ethyl cellulose to prepare a titanium oxide paste for screen printing.

The titanium oxide paste was applied to the electron transport layer and dried. The resultant member was fired at 500° C. for 30 minutes in the air to form a porous layer constituted by a porous titanium oxide coating (titanium coating) having a thickness of 0.2 μm.

A dimethyl sulfoxide (DMSO) solution containing 3 mol/L of PbI₂ was prepared. This PbI₂ solution was applied to the porous layer by spin coating. The substrate was heat-treated on a hot plate at 130° C. to form a PbI₂ film.

An isopropyl alcohol solution containing 1 mol/L of CH₃NH₃I was prepared. The substrate was immersed in the CH₃NH₃I solution and dried to form a CH₃NH₃PbI₃ perovskite layer as a light-absorbing layer. The light-absorbing layer had a thickness of about 300 nm.

A chlorobenzene solution was prepared so as to contain 60 mmol/L of Spiro-OMeTAD, 30 mmol/L of lithium bis(fluorosulfonyl)imide (LiTFSi), 200 mmol/L of tert-butylpyridine (tBP), and 1.2 mmol/L of a Co complex (FK209, manufactured by Dyesol Limited). This solution was applied to the light-absorbing layer by spin coating to form a hole transport layer. The hole transport layer had a thickness of about 100 nm.

Finally, gold was deposited on the hole transport layer to form a layer having a thickness of 80 nm. Thus, a second current-collector electrode was formed.

### Example 2

A perovskite solar cell was produced as in the production steps for the perovskite solar cell of Example 1 except that the PbI₂ concentration of the solution for forming the light-absorbing layer was changed to 4 mol/L.

### Comparative Example 1

A perovskite solar cell was produced as in the production steps for the perovskite solar cell of Example 1 except that the solution for forming the light-absorbing layer was prepared as a DMSO solution containing 1 mol/L of PbI₂ and 1 mol/L of CH₃NH₃I. This solution was applied to the porous layer 4 by spin coating.

### Comparative Example 2

A perovskite solar cell was produced as in the production steps for the perovskite solar cell of Comparative Example 1 except that the PbI₂ concentration of the solution for forming the light-absorbing layer was changed to 3 mol/L.

### Comparative Example 3

A perovskite solar cell was produced as in the production steps for the perovskite solar cell of Comparative Example 1 except that the PbI₂ concentration of the solution for forming the light-absorbing layer was changed to 4 mol/L.

### Evaluation for Properties

Composition Analysis

The light-absorbing layer of each perovskite solar cell was subjected to EPMA measurement. In each of Examples and Comparative Examples, the perovskite compound contained in the light-absorbing layer is CH₃NH₃PbI₃. That is, the perovskite compound is represented by a compositional formula ABX₃ where the cation A is CH₃NH₃⁺, the cation B is Pb²⁺, and the halogen anion X is I⁻. Thus, the numbers of moles of the cation A and cation B were determined from the analysis results of the light-absorbing layer in terms of Pb and C. On the basis of the determined numbers of moles, the ratio of the number of moles of the cation A to the number of moles of the cation B was calculated. The calculated results are described as “Number-of-Mole Ratio” in Table 1.

Each of the perovskite solar cells of Examples 1 and 2 and Comparative Example 3, the light-absorbing layer was measured by XRD. The peak intensity derived from a (001) plane of PbI₂ in the light-absorbing layer was determined as I[BX₂]. The peak intensity derived from a (110) plane of CH₃NH₃PbI₃ was determined as I[ABX₃]. On the basis of these peak intensities, a peak intensity ratio I[BX₂]/I[ABX₃] was calculated. The results are described in Table 1.

Note that the EPMA measurement and the XRD measurement were carried out after formation of the light-absorbing layer and before formation of the hole transport layer 7.

Durability Measurement

A solar simulator was used to irradiate a perovskite solar cell with light at an illuminance of 100 mW/cm². After the current-voltage characteristic stabilized, the current-voltage characteristic was measured and the conversion efficiency was determined as the initial conversion efficiency. After the initial conversion efficiency was determined, the perovskite solar cell was subjected to a heating test at 85° C. for 300 hours. After the heating test, the conversion efficiency was determined again on the basis of the measurement of current-voltage characteristic. The ratio of the conversion efficiency after the heating test to the initial conversion efficiency was calculated as a retention ratio.

TABLE 1

| | | | | | Conversion | |
|---|---|---|---|---|---|---|
| | | | | Initial | Efficiency | |
| | PbI₂ (mol/L)/ | | XRD peak | Conversion | After Heat- | Retention |
| | CH₃NH₃I (mol/L) | Number-of- | intensity | Efficiency | ing Test | Ratio |
| | of Solution | Mole Ratio | ratio | (%) | (%) | (%) |
| Example 1 | 3/1 | 0.89 | 3.5 | 10 | 9 | 90 |
| | (separate | | | | | |
| | solutions) | | | | | |
| Example 2 | 4/1 | 0.86 | 7.7 | 8 | 7 | 88 |
| | (separate | | | | | |
| | solutions) | | | | | |
| Comparative | 1/1 | 4.7 | — | 15 | 0.8 | 5 |
| Example 1 | (in the same | | | | | |
| | solution) | | | | | |
| Comparative | 3/1 | 1.3 | — | 13 | 2.6 | 20 |
| Example 2 | (in the same | | | | | |
| | solution) | | | | | |
| Comparative | 4/1 | 1.1 | 0.11 | 12 | 4.8 | 40 |
| Example 3 | (in the same | | | | | |
| | solution) | | | | | |

Table 1 indicates that the perovskite solar cells of Example 1 and Example 2 have retention ratios of 88% or more after the heating test. On the other hand, the perovskite solar cells of Comparative Examples 1 to 3 have retention ratios as low as 40% to 5%.

Examples have demonstrated that the ratio of the number of moles of the cation A to the number of moles of the cation B in the light-absorbing layer is set to 0.5 or more and 0.9 or less to thereby provide a perovskite solar cell having enhanced durability, and that the light-absorbing layer is formed such that the peak intensity I[BX₂] is higher than the peak intensity I[ABX₃] in an XRD measurement result to thereby provide a perovskite solar cell having enhanced durability.

A perovskite solar cell according to the present disclosure is useful as a photovoltaic element or an optical sensor.

What is claimed is:

1. A perovskite solar cell comprising:
a first electrode;
an electron transport layer on the first electrode, containing a semiconductor;
a porous layer on the electron transport layer, containing a porous material;
a light-absorbing layer on the porous layer, containing a first compound and a second compound different from the first compound, the first compound having a perovskite structure represented by a compositional formula ABX₃ where A represents a monovalent cation, B represents a divalent cation, and X represents a halogen anion, the second compound containing the divalent cation; and
a second electrode on the light-absorbing layer, wherein
a ratio of a number of moles of the monovalent cation in the light-absorbing layer to a number of moles of the divalent cation in the light-absorbing layer is 0.5 or more and 0.9 or less.

2. The perovskite solar cell according to claim 1, wherein the ratio of the number of moles of the monovalent cation in the light-absorbing layer to the number of moles of the divalent cation in the light-absorbing layer is 0.8 or more and 0.9 or less.

3. A perovskite solar cell comprising:
a first electrode;
an electron transport layer on the first electrode, containing a semiconductor;
a porous layer on the electron transport layer, containing a porous material;
a light-absorbing layer on the porous layer, containing a first compound and a second compound different from the first compound, the first compound having a perovskite structure represented by a compositional formula ABX₃ where A represents a monovalent cation, B represents a divalent cation, and X represents a halogen anion, the second compound being represented by a compositional formula BX2 where B represents the divalent cation, and X represents the halogen anion; and
a second electrode on the light-absorbing layer, wherein
In a CuKα X-ray diffraction pattern of the light-absorbing layer, a peak intensity of a (001) plane of the second compound is higher than a peak intensity of a (110) plane of the first compound.

4. The perovskite solar cell according to claim 3, wherein a ratio of the peak intensity of the (001) plane of the second compound to the peak intensity of the (110) plane of the first compound is 3.5 or more.

5. The perovskite solar cell according to claim 1, wherein the monovalent cation comprises at least one selected from the group consisting of a methylammonium cation and a formamidinium cation.

6. The perovskite solar cell according to claim 1, wherein the divalent cation comprises at least one selected from the group consisting of Pb²⁺, Ge²⁺, and Sn²⁺.

7. The perovskite solar cell according to claim 1, further comprising a hole transport layer between the light-absorbing layer and the second electrode.

8. The perovskite solar cell according to claim 1, wherein the porous material comprises titanium oxide.
